(19) United States
(12) Patent Application Publication
(10) Pub. No.: US 2008/0018340 A1
(43) Pub. Date: Jan. 24, 2008

(54) Method for Determining Loop Impedance Active and Reactive Components of an Alternative Current Network

(75) Inventors: Axel Arnou, Paris (FR); Alban Sirot, Paris (FR); Jean Delande, Paris (FR)

Correspondence Address: LEYDIG VOIT & MAYER, LTD, 700 THIRTEENTH ST. NW, SUITE 300, WASHINGTON, DC, 20005-3960, US

(73) Assignee: CHAUVIN ARNOUX, Neuilly sur Seine (FR)

(21) Appl. No.: 11/571,279

(22) PCT Filed: Jul. 1, 2005
(86) PCT No.: PCT/FR05/01691

§ 371 Date: Mar. 12, 2007

(30) Foreign Application Priority Data
Jul. 6, 2004 (FR) 04 07 489

(51) Int. Cl. G01R 31/08

(52) U.S. Cl. 324/525

(57) ABSTRACT

A method for determining loop impedance active and reactive components of an alternating current network and a device for carrying out the method. The active and reactive components are determined by applying a test load to the loop, by measuring the loop voltage prior to the application of the test load and, when the test load is applied, measuring the voltage time evolution during the application of the test load and determining the active resistance R and reactive inductance L parts of the loop impedance by jointly analysing differential measurements of the loop voltage and the time evolution of the test load voltage.

The invention relates to a method for measuring the loop impedance of an alternating current supply network as well as a measuring device for implementing this method.

In electrical installations, safety standards require that a certain number of criteria relating to the safety of persons and property be observed.

In particular, proper grounding of the metal frames of machines, as well as the presence of appropriate protective devices against short circuits and against defective insulation prove to be indispensable. In this regard, the devices serving to monitor electrical installations must, among other things, make it possible:
to check the characteristics of the grounding circuits, so that, in the event of defective insulation, the ground potential elevation does not reach dangerous values,
to quantitatively evaluate the characteristics of the supply network, so as to correctly size the short-circuit protection elements.

Whether the characteristics of the grounding circuits or those of the supply network are involved, it is necessary to consider the reactive portion of the impedance, because it generally corresponds to a significant portion (up to 50%) of the total impedance.

As concerns the grounding circuits, the measurement of the ground impedance is carried out with a dedicated measuring device (ground ohmmeter) and two additional ground posts.

However, in urban areas, this type of measurement often proves difficult to carry out because, the majority of the time, it is impossible to install the ground posts. In this case, the value of the “line conductor/protective conductor” loop impedance can be taken into account in place of the ground impedance in order to comply with regulations relating to protection against the risk of electrical shocks associated with defective insulation.

When it is a question of loop impedance measurements, it is appropriate to differentiate between two very distinct types of measurement:
the measurement of loop impedance of the line and neutral circuit (Z_{LN}), the impedance referred to as “line circuit impedance” in the remainder of the text; and
the measurement of loop impedance of the line and grounding circuit (Z_{LPE}), the impedance referred to as “grounding circuit impedance” in the remainder of the text.

The measurement of the line circuit impedance makes it possible to determine the value of the short-circuit current for the installation. Knowing this value, the installer can thereby size the safety devices (fuses, circuit breakers, etc.), these latter necessarily having to be capable of withstanding this short circuit for the time span required to trigger them.

The measurement of the grounding circuit impedance makes it possible to set the sensitivity of the differential circuit breaker (assigned operating differential current), knowing that, in the event of defective insulation, the ground potential elevation must not reach a value considered to be dangerous to people.

Until now, the measurement of loop impedance(s) of an installation was limited to direct application of Ohm's law, i.e.:
either by injecting a current “I” into the loop circuit, under steady state conditions, then measuring the potential difference “V” appearing across said loop circuit, and finally by obtaining the quotient V/I,
or by applying a potential difference under steady state conditions across the loop circuit, then measuring the steady state current passing through said loop circuit, and finally by obtaining the quotient V/I.

This method, which is relatively simple to implement, nevertheless provides only the loop impedance module. Such being the case, it may be advantageous to know if the impedance is predominantly linked to parasitic resistance (connections, length of the conductors . . . ) or to a self-inductive effect: inductance(s) returned by the head transformer, length and spatial arrangement of the supply conductors, etc. Knowledge of the resistive component and the inductive component does indeed provide information that helps to locate the faulty element or elements in the electrical installation. For example, if the impedance has a rather inductive character, it is more likely that the power supply transformer is the cause.

Furthermore, the principle that is commonly used with off-the-shelf devices, and that uses steady state current operating conditions, requires significant measuring time (necessity of waiting for the transient state to disappear). Thus, it can be applied only to relatively weak currents, given the fact that it is physically impossible to dissipate a great deal of energy in the measuring device. Consequently, the measured signal is also of low amplitude, which does not guarantee sufficient accuracy.

The purpose of the invention is to eliminate the above-stated disadvantages.

The purpose of the invention is achieved with a method for determining the active and reactive loop impedance components of an alternating current supply network providing the current under a supply voltage, i.e., the measurement of the loop voltage and current, followed by a subsequent calculation of the module for the active and reactive loop impedance components, the loop including a network line conductor and at least one of the following conductors:
a neutral network conductor, or
a protective grounding conductor.

In a method according to which a load is applied to the loop (referred to as a “test load” in the remainder of this description), the loop voltages before the test load is applied (“no load” measurement) and when the test load is applied (“load” measurement) are measured, respectively; the temporal course of the current during the period in which the test load is applied is measured, and the active (resistance “R”) and reactive (inductance “L”) portions of the loop impedance are determined by conjointly analyzing, on the one hand, the differential loop voltage measurements, and, on the other hand, the temporal course of the current in the test load, in accordance with the following detailed description.

The following formulas are used to calculate the active and reactive loop impedance components:

$$R = \frac{{\hat{I}}_{t 1} \cdot \underline{Δ {U}_{2}} - {\hat{I}}_{t 2} \cdot \underline{Δ {U}_{1}}}{{\hat{I}}_{t 1} \cdot \underline{{I}_{2}} - {\hat{I}}_{t 2} \cdot \underline{{I}_{1}}}$$

$$L = \frac{\underline{Δ {U}_{2}} \cdot \underline{{I}_{1}} - \underline{Δ {U}_{1}} \cdot \underline{{I}_{2}}}{{\hat{I}}_{t 2} \cdot \underline{{I}_{1}} - {\hat{I}}_{t 1} \cdot \underline{{I}_{2}}}$$

where:

Îₜ₁ represents the instantaneous value “Ipic1” of the current in the test load at the end of the time period “T1,”

Îₜ₂ represents the instantaneous value “I_{pic2}” of the current in the test load at the end of the time period “T2,”

ΔU₁ represents the full value of the voltage difference [“no load”−“load”] during the time period “T1,”

ΔU₂ represents the full value of the voltage difference [“no load”−“load”] during the time period “T2,”

I₂ represents the full value of the current in the test load during the time period “T1,”

I₂ represents the full value of the current in the test load during the time period “T2.”

According to the invention, the test load is applied so that the current being measured is in the form of a high-amplitude, short-duration current pulse, the variation in the loop voltage is analyzed dynamically via differential measurement of the loop voltage before and during application of the test load, and the temporal course of the current is analyzed during application of the test load.

Therefore, the system according to the invention consists of applying a high-amplitude, short-duration current pulse via application of a test load, in order to dynamically analyze the course of the loop voltage and the current in the test load.

This pulse is advantageously applied on the peak or in immediate proximity to the peak of the sinusoidal voltage. The advantage of such a system is that the current applied is significant and that therefore the signal being measured has an optimal signal-to-noise ratio. Furthermore, this principle makes it possible to extract the real portion and the reactive portion of the impedance in the form of two separate values, which provides additional information to the user, and thereby makes it easy to use.

Furthermore, the invention also relates to the following characteristics, considered separately or in any technically possible combination thereof:
the current pulse is obtained by an electronic control for applying the test load, this control being triggered by the measuring instrument performing the differential measurements of the loop voltage and the measurements of the temporal course of the current;
the test voltage is applied repeatedly so that the measurement of voltage and of the temporal course of the current can be performed, totaled and averaged over several pulses;
the test load is applied repeatedly so that the current can be measured in the form of at least two pulses per period of the network voltage;
from one period of the network voltage to another, the sequence of a pulse before application of the load and of a pulse during application of the load is inverted;
the impedance is obtained by respectively integrating the results of measurements of the differential loop voltage and current.

The purpose of the invention is also achieved with a device for measuring and determining loop impedance in order to implement the above-described method. This device includes an input divider bridge designed to be connected to an electrical network in which the loop impedance must be measured. According to the embodiment chosen, a single or double divider bridge is involved. The measuring device further includes, for the respective measurements of a voltage and current from which the loop impedance must be determined, at least one integrator connected to the divider bridge via a buffer storage, an on/off control, as well as measuring and processing means receiving signals coming from the integrator or integrators and including means for making the measurement results available.

Other characteristics and advantages of the invention will become apparent from the following detailed description of the measuring method and device, with reference to the drawings in which:

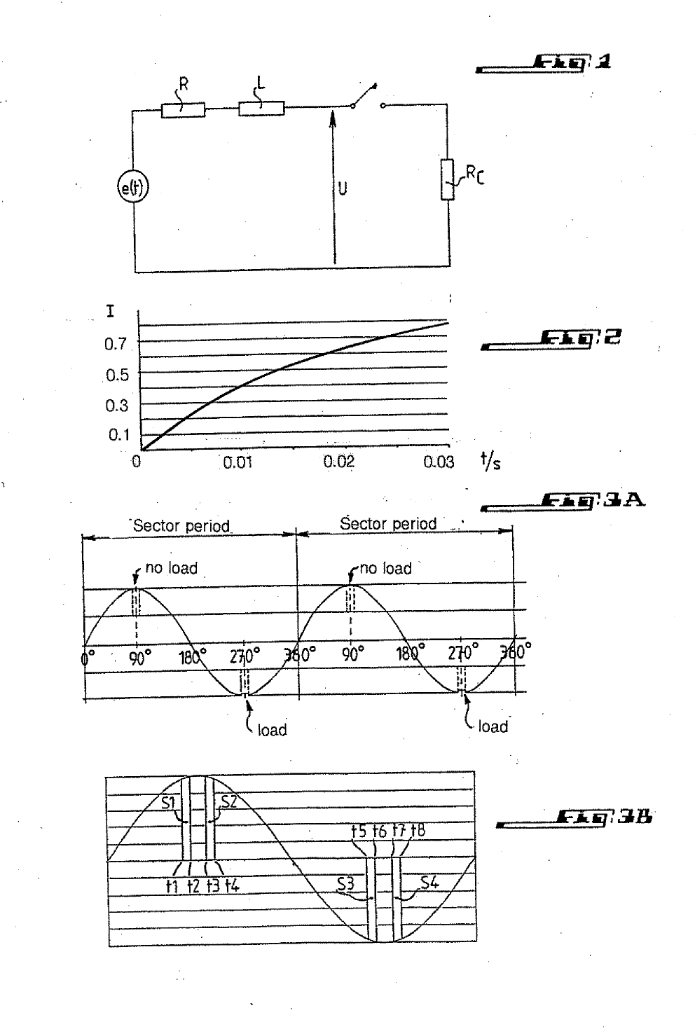

FIG. 1 shows the block diagram of a measuring circuit according to the invention,

FIG. 2 shows the typical course of the current during application of the test load,

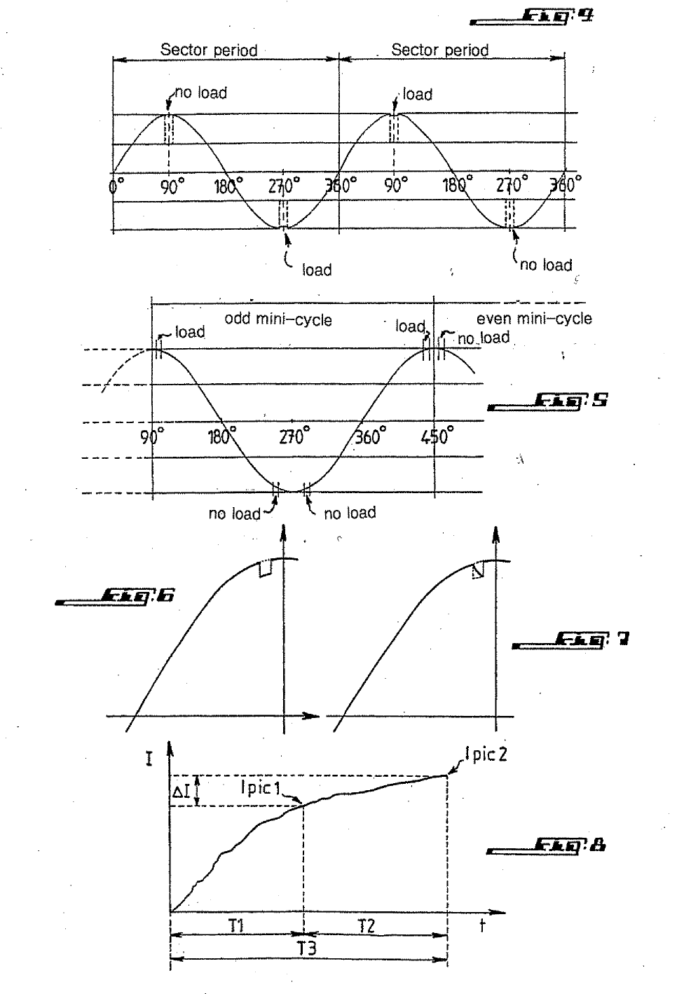

FIG. 3A shows a first possibility for applying current pulses,

FIG. 3B shows a second possibility for applying current pulses,

FIG. 4 shows an extension of the diagram of FIG. 3A for explaining the method according to the invention,

FIG. 5 shows the notion of mini-cycles,

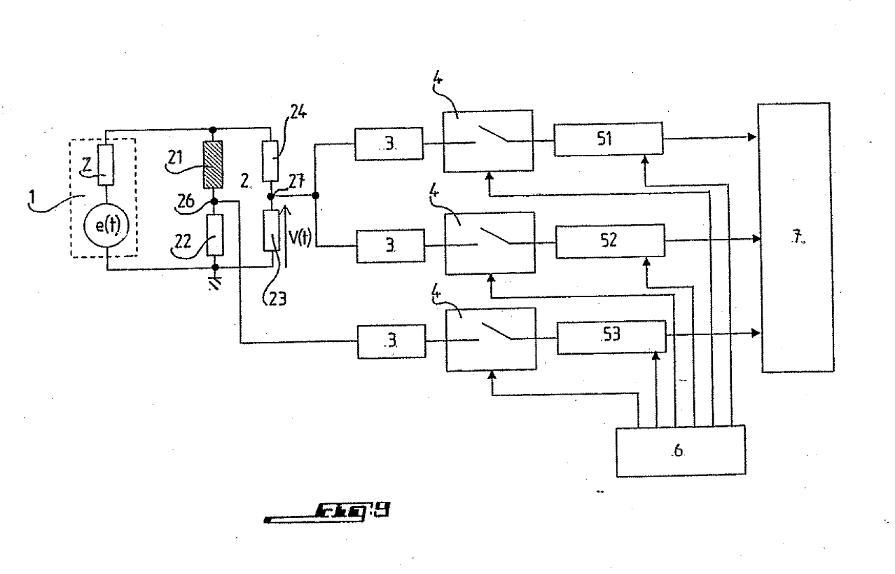

For illustrative purposes, FIGS. 6 and 7 respectively show the voltage drop of the network during application of a current pulse in relation to a purely resistive type of load or one with an inductive component,

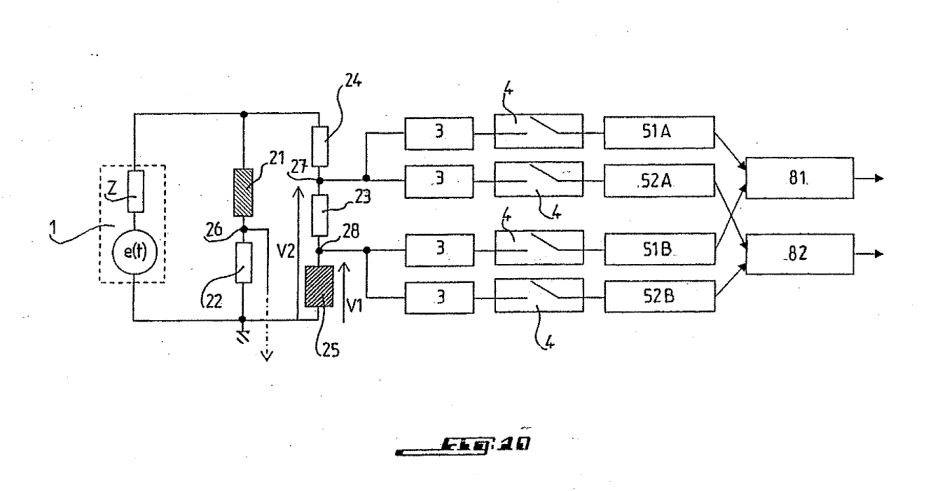

FIG. 8 shows the typical course of the current during application of the test load, and

FIGS. 9 and 10 show block diagrams of a measuring circuit with a loop impedance measuring device according to the invention.

The principle of measurement is illustrated by the diagram in FIG. 1, where:
e(t) is the sinusoidal voltage supplied by the electrical supply network (sector),
R and L symbolize the resistance and inductance of the line circuit or the grounding circuit,
R_{C} is a load that is electronically controlled by the measuring device and that makes it possible to create the current pulse.

The pulse shape is directly linked to the time constant τ of the circuit:
τ=L/(R+R_{C})

FIG. 2 illustrates the course of this pulse current.

The phenomena characterizing the resistive portion and inductive portion of the line (or ground) impedance are, on the one hand, the variation in voltage between a “no-load” pulse (null current) and a “load” pulse (non-null current) and, on the other hand, the temporal course of the current during application of the load.

The voltage delivered by the sector has an approximately symmetrical shape (central symmetry), as shown in FIG. 3A. This particular feature is advantageously put to use in order to obtain the difference, from an analog or digital standpoint, “no-load voltage”−“load voltage.” As a matter of fact, in order to accomplish this, it suffices to measure the “no-load” positive half-wave while the negative half-wave is measured “under load.” The difference is a simple arithmetic sum of the two measurements, given that the half-waves have opposite signs.

In fact, the principle of measurement corresponds to a “differential” measurement of the signal, since it is necessary to obtain the difference between the “no-load” signal and the “load” signal; the result of this difference is linked to the internal impedance value of the source. The measurement thus advantageously uses the fact that there is a positive half-wave, then a negative half-wave, in order to obtain this difference.

All of the processing and calculations to be carried out as part of measuring and then determining the loop impedance according to the invention are conducted electronically, either by integrators, summers, subtractors, hard-wired analog or digital multipliers, or by means of microprogrammed components, e.g., such as microprocessors, DSPs, FPGAs, and CPLDs, etc.

In one of the preceding paragraphs, the hypothesis was put forth that two half-waves of the electrical network were of the same shape (central symmetry). However, this is not always the case in reality.

In order to make this lack of symmetry disappear, or at least sharply reduce it, the role of the half-waves is inverted at each period: for example, in a first phase, the positive half-wave serves as the “load” pulse and the negative half-wave serves as the “no-load” pulse. Then, in a second phase, the positive half-wave serves as the “no-load” pulse and the negative half-wave serves as the “load” pulse. Reference is then made to the “even” sector period and the “odd” sector period, respectively.

As concerns the integration of the signals, two partial sums are then obtained concurrently: the one corresponding to the even periods and the other corresponding to the odd periods.

Once these two sums have been carried out, the difference between these two sums is calculated. FIG. 4 explains the measuring process.

In order to be free of distortions that may arise on the peak of the sinusoidal voltage (clipping due to diode/condenser load or, more typically, third-harmonic distortion and/or higher-order [distortion]), the measurement is carried out on each side of the peak. Thus, for each half-wave peak, two measuring pulses are used instead of one, these two pulses being situated on each side of the half-wave peak, as shown in FIG. 5.

In order to carry out the subtraction of the results “no-load measurement”−“load measurement,” the “no-load” and “load” pulses are systematically applied to the opposing half-waves. Thus, for example, a “no-load” pulse is applied to the trailing edge of the positive half-wave, then a “load” pulse to the leading edge of the negative half-wave, etc. This principle is also used to prevent the existence of two consecutive integrations having the same sign, e.g., two “no-load” integrations that might follow one another, because this would cause the integrator to become saturated.

This requires that the measurement begin on the trailing edge of a sine wave, hence the notion of a “mini-cycle” (see FIG. 5).

Several mini-cycles will be linked together, not exceeding a number Nₘₐₓ, so as to limit the overall measurement time if the “no-load pulse−load pulse” differential voltage is very low or even null, and until the output of each integrator reaches a threshold. This threshold is set to have the largest dynamic possible, but also to prevent saturation of the integrator.

In addition, in order to minimize the influence of potential dissymmetry, an averaging operation is carried out using the absolute values of the measurement results obtained:

1. Starting with a positive half-wave, as shown in FIG. 5, which provides an overall negative integration result because, as an absolute value, the “load” value is lower than the “no-load” value;

2. Starting with a negative half-wave, which provides an overall positive integration result because, as an absolute value, the “no-load” value is greater that the “load value.”

This leads to the notion of odd mini-cycles, which begin with a “load” pulse, and to that of even mini-cycles, which begin with a “no-load” pulse. Since the results of these two series of measurements have opposite signs, it is also possible to obtain the average thereof by calculating the algebraic difference of the results.

The purpose of these alternating modes of measurement is also to not render the measuring pulse current too dissymmetrical.

FIG. 5 illustrates the notion of even and odd mini-cycles. In this example, integration begins with a “load” pulse and on the end of the positive half-wave. In terms of an integral, it is roughly counterbalanced by the “no-load” integration on the leading edge of the negative half-wave.

In practice, and in certain cases, the resultant is near zero (but not completely null because the electrical network generally has a significant internal impedance). If the result of the integration is low, it is possible to total several differential integration cycles (“no-load”−“load”), by using the trailing edge of the negative half-wave to carry out a “no-load” integration, then the “load” integration on the leading edge of the positive half-wave. Thus, there are then a total of two “load” integrations on the positive half-wave and two “no-load” integrations on the negative half-wave. For an odd mini-cycle, the result is therefore: two times the integral of the difference between “load” pulse and “no-load” pulse.

When a “load” pulse is suddenly applied to the voltage delivered by the network, a brief voltage drop follows.

The shape of this voltage drop depends on the structure of the internal impedance of the source.

If this internal impedance is purely resistive, the voltage drop has a crenellated shape (see FIG. 6);

If this internal impedance has a self-inductive component, the latter impedes any sudden variation in the current. The temporal course of the voltage drop then has an approximately exponential shape (see FIG. 7). In this latter case, the shape of the load current also has an exponential appearance (see the curve in FIG. 8).

Besides the integration of the current, the determination of the resistive portion and the self-inductive portion of the circuit impedance requires knowledge of the values of the voltage integrals during the time period T1 and the time period T2, according to the notations in FIG. 8.

These operations are carried out by means of analog integrators or by totaling of measurement samples. In the latter case, this involves one of the tasks performed by the microprogrammed logic device. In a first measurement phase, the integrator carries out the integral of the voltage over time T1 and does so during N consecutive mini-cycles. The value of N is fixed, either by the fact that the output of the integrator reaches a certain predetermined threshold (starting with this threshold, the cumulative total is considered to be sufficient), or by a “time out” (case where the signal is very weak or even null, in which case N=N_{MAX}). The integrator output value is then stored by the processing unit.

In a second phase, the integrator is reset to zero and then carries out the integral of the voltage over time T2, during N consecutive mini-cycles, the value of N being fixed in the same way as that described in the previous paragraph.

Using these measured and integrated values of time, current and voltage, the calculations provided together at the end of the description show how the values of the resistive portion (resistance “R”) and of the reactive portion (inductance “L”) of the circuit being characterized are calculated. Once calculated, these values “R” and “L” are then displayed on the screen of the measuring device.

The fact of using a single integrator for the voltage is costly in terms of time, The use of two integrators mounted in parallel, one for the integration of the voltage during T1 and the other for the integration of the voltage during T2, makes it possible to divide the measuring time by two. The impact is very significant in terms of heat build-up inside the device.

In conclusion, and during the pulses, whether they be of the “no-load” or “load” type, the measuring and processing chain carries out the following operations simultaneously:

1. Integration of the voltage during the time T1 (role of integrator No. 1),

2. Integration of the voltage during the time T2 (role of integrator No. 2),

3. Integration of the current during the time T3=T1+T2 (role of integrator No. 3).

In a measuring device designed to implement the measuring method according to the invention, integrators No. 1 and No. 2 are produced by means of operational amplifiers (conventional integrator assembly), while the integration of the current (integrator No. 3) is carried out digitally: totaling of the measurement samples obtained via analog-to-digital conversion. However, it is entirely possible to use either digital or analog integrators in order to carry out these three signal integrations.

FIG. 9 is not, strictly speaking, the exact diagram of such a measuring device, but it provides an aid to understanding the principle of measurement according to the invention.

The measuring device thus includes a double input divider bridge 2 designed to be connected to an electrical network 1 in which the loop impedance must be measured. This double input divider bridge 2 contains the four customary resistors 21 to 24, the resistor 21 consisting of a controlled load and the resistor 22, a measuring shunt resistor. The interconnection node between the resistors 21 and 22, referenced as 26, serves to measure the course of the current during the time interval T3, while the interconnection node between the two other resistors 23, 24, referenced as 27, serves to measure the voltage during the time intervals T1 and T2, respectively.

The pulses coming from the interconnection node 27 are brought toward the integrators 51 and 52, via two buffer stages 3 and two on/off controls 4 dedicated to the voltage integration during time T1 and during T2, respectively. Similarly, the pulses coming from the interconnection node 26 are brought toward the integrator 53 via the buffer stage 3 and the on/off control 4 dedicated to integration of the current during the time T3. The operation of the controls 4 and the integrators 51 to 53 is controlled by a sequencing logic 6. The results of the integrations carried out by the integrators 51 to 53 are sent to measuring and processing means 7, which includes means for making the measurement results available

In actual practice, the “collective” voltage measurements must be carried out differentially, because the foot of the voltage divider bridge is not at the ground potential “measurement.” As a matter of fact, it is imperative that protective electronic components be inserted between the ground “measurement” and this bridge foot,

Thus, it is necessary to double the number of integrators for measuring the voltage. FIG. 10 shows that there are indeed two pairs of integrators referenced as 51A, 52A, 51B, 52B, respectively, which also involves providing the device with twice the number of buffer stages and on/off controls. The outputs of the integrators are connected to subtractors 81, 82. The output of each subtractor thus supplies the integral of the differential voltage present across the resistor 23.

FIG. 10 further shows the placement, in the input divider bridge 2, of a protective component, which is arranged in series with the resistors 23, 24 and which produces an additional interconnection node 28.

The theoretical calculations on which the method of the invention is based are as follows.

The function e(t) is assumed to be isochronous. The equation of the voltage across the load “R_{C}” is as follows, with reference being made to FIG. 1:

$${U}_{Rc} = e ( t ) - R \cdot i ( t ) - L \cdot \frac{ⅆ i}{ⅆ t} \qquad [ EQ1 ]$$

The current i₁ and the index “_{Rc1}” correspond to the no-load measurement while the current i₂ and the index “_{Rc2}” correspond to the load measurement, thus:

$$Δ {U}_{Rc} = {U}_{Rc 2} - {U}_{Rc 1} \\ = R \cdot ( {i}_{2} ( t ) - {i}_{1} ( t ) ) - {i}_{1} ( t ) ) + L \cdot ( \frac{ⅆ {i}_{2}}{ⅆ t} - \frac{ⅆ {i}_{1}}{ⅆ t} ) \qquad [ EQ5 ]$$

Assuming that Δi(t)=i₂(t)−i₁(t), it follows that:

$$\begin{matrix}Δ {U}_{Rc} = R \cdot ( {i}_{2} ( t ) - {i}_{1} ( t ) ) + L \cdot ( \frac{ⅆ {i}_{2}}{ⅆ t} - \frac{ⅆ {i}_{1}}{ⅆ t} ) \\ = R \cdot Δ i ( t ) + L \cdot \frac{ⅆ ( Δ i )}{ⅆ t}\end{matrix} \qquad [ EQ6 ] and [ EQ7 ]$$

By using [EQ5] and by integrating side by side between the time points tₐ and t_{b}, one obtains:

$${\int }_{ta}^{tb} ( {U}_{Rc 2} ( t ) - {U}_{Rc 1} ( t ) ) ⅆ t = R \cdot {\int }_{ta}^{tb} ( {i}_{2} ( t ) - {i}_{1} ( t ) ) ⅆ t + L \cdot {\int }_{ta}^{tb} ( \frac{ⅆ {i}_{2}}{ⅆ t} - \frac{ⅆ {i}_{1}}{ⅆ t} ) ⅆ t \qquad [ EQ9 ]$$

which yields:

$$\begin{matrix}{\int }_{ta}^{tb} ( {U}_{Rc 2} ( t ) - {U}_{Rc 1} ( t ) ) ⅆ t = R \cdot {\int }_{ta}^{tb} ( {i}_{2} ( t ) - {i}_{1} ( t ) ) ⅆ t + L \cdot ( {[ {i}_{2} ( t ) ]}_{ta}^{tb} - {[ {i}_{1} ( t ) ]}_{ta}^{tb} ) & [ EQ10 ] \\ With \text{:} {i}_{2} ( t ) = \frac{{U}_{Rc 2} ( t )}{Rc 2} and {i}_{2} = \frac{{U}_{Rc 1 ( t )}}{Rc 1} & [ EQ11a ] and [ EQ11b ]\end{matrix}$$

In the case of our measurement, “Rc” is, very generally speaking, the load resistance applied by our measuring device. “Rc2” is the load resistance, the value of which will cause the electrical network to which it is connected to react. On the other hand, “Rc1” is the open-circuit resistance; the current i₁(t) is therefore null; the equation [EQ10] can thus be simplified, which is now written as follows:

$$\begin{matrix}\begin{matrix}{\int }_{ta}^{tb} ( {U}_{Rc 2} ( t ) - \\ {U}_{Rc 1} ( t ) ) ⅆ t\end{matrix} = R \cdot {\int }_{ta}^{tb} {i}_{2} ( t ) ⅆ t + L \cdot {[ {i}_{2} ( t ) ]}_{ta}^{tb} \\ = R \cdot {\int }_{ta}^{tb} {i}_{2} ( t ) ⅆ t + L \cdot {i}_{2} ( {t}_{b} ) - L \cdot {i}_{2} ( {t}_{a} )\end{matrix} \qquad [ EQ12 ]$$

Such being the case, i₂(tₐ)=0, thus the equation can be written in the following form:

$${\int }_{ta}^{tb} ( {U}_{Rc 2} ( t ) - {U}_{Rc 1} ( t ) ) ⅆ t = R \cdot {\int }_{ta}^{tb} {i}_{2} ( t ) ⅆ t + L \cdot {i}_{2} ( {t}_{b} ) \qquad [ EQ12 bis ]$$

As a matter of fact, let it be noted that the device makes it possible to measure:

U_{RC1}(t), U_{RC2}(t) as well as i₂(t).

We will now call:

$$\begin{matrix}{U}_{Load} ( t ) = {U}_{Rc 2} ( t ) , {U}_{No - load} ( t ) \\ = {U}_{Rc 1} ( t ) and {i}_{Load} ( t ) \\ = {i}_{2} ( t ) .\end{matrix} \\ hence \text{:} \\ {\int }_{ta}^{tb} ( {U}_{Load} ( t ) - {U}_{N - load} ( t ) ) ⅆ t = R \cdot {\int }_{ta}^{tb} {i}_{Load} ( t ) ⅆ t + L \cdot {i}_{Load} ( tb ) \qquad [ Eq13 ]$$

The equation [EQ13] is then written:
ΔU=R·I+L·Î₁ [EQ14]

The equation [EQ13] makes use of two integrations and an instantaneous value:
First Integration:

$$\underline{Δ U} = {\int }_{t 1}^{t 2} ( {U}_{Load} ( t ) - {U}_{No - load} ( t ) ) ⅆ t$$

Second Integration:

$$\underline{I} = {\int }_{t 1}^{t 2} {i}_{Load} ( t ) ⅆ t$$

Instantaneous Value:
Î₁=L·i_{Load}(t) with i_{change}(t)

The physical representation of the measurement is as follows: the signal s(t) is ideally represented by the function s(t)=sₘₐₓ·sin(ω·t); we will be working via axial symmetry and via central symmetry. Based on the temporal markers selected, the function is even or odd.

When double pulses are applied in the time intervals indicated in FIG. 3B, the signals are expressed by the following four integrals:

$$S 1 = {\int }_{t 1}^{t 2} s ( t ) ⅆ t , \\ S 2 = {\int }_{t 3}^{t 4} s ( t ) ⅆ t . \\ S 3 = {\int }_{t 5}^{t 6} s ( t ) ⅆ t , \\ S 1 = {\int }_{t 7}^{t 8} s ( t ) ⅆ t \qquad [ EQ 15 ]$$

By using the angular representation of the signal s(t)=sₘₐₓ·sin(ω·t), we have:
θ=ω·t and thus: θ₁=ω·t₁; θ₂=ω·t₂; θ₃=ω·t₃; θ₄=ω·t₄

Assuming that θ₂=θ₁+α and θ₄=θ₃+α, as well as

$${θ}_{1} = \frac{π}{2} - {ϕ}_{1} and {θ}_{4} = \frac{π}{2} + {ϕ}_{1} and \qquad [ EQ 16 a ] and [ EQ 16 b ]$$

where α=f(tₙ₊₁−tₙ) thus represents the integration time. The equations [EQ16a] and [EQ 16b] imply: sin(θ₁) sin(θ₄) and this is true irrespective of φ₁. Consequently, given the relationships that join θ₁ and θ₄ to θ₂ and θ₃, respectively, it can be deduced that: sin(θ₂)=sin(θ₃), irrespective of φ₁.
By extension, taking the four equations [EQ15] and knowing that s(t) has the form s(t)=sₘₐₓ·sin(ω·t), it can be said that:

$${\int }_{t 1}^{t 2} s ( t ) ⅆ t = {\int }_{t 3}^{t 4} s ( t ) ⅆ t and {\int }_{t 5}^{t 6} s ( t ) ⅆ t = {\int }_{t 7}^{t 8} s ( t ) ⅆ t \qquad [ EQ 16 c ]$$

Such being the case, by construction, |θ₁| and |θ₂| are equal to |θ₇| and |θ₈|, respectively. Since s(t) is a sinusoidal function, we have:

$${\int }_{t 1}^{t 2} s ( t ) ⅆ t = \vert {\int }_{t 7}^{t 8} s ( t ) ⅆ t \vert ;$$

thus, the following relationship can be developed:

$$\vert {\int }_{t 1}^{t 2} s ( t ) ⅆ t \vert = \vert {\int }_{t 5}^{t 4} s ( t ) ⅆ t \vert = \vert {\int }_{t 5}^{t 6} s ( t ) ⅆ t \vert = \vert {\int }_{t 7}^{t 8} s ( t ) ⅆ t \vert$$

This quadruple equality is important for carrying out the integration of the signal, the latter being carried out over various time intervals spread out over several periods.

Currently, the integration may be noted as:

$$\vert {\int }_{{t}_{a}}^{{t}_{a + 1}} s ( t ) ⅆ t \vert$$

Measurement and calculation: In terms of measuring, and by taking up equation [EQ14] again, it is possible to physically measure the following quantities. ΔU, I and Îₜ (equation with 2 unknowns: R and L).

By performing two separate measurements carried out over the same segment tₙ and tₙ₊₁, a system with 2 equations and 2 unknowns is obtained:

Measurement 1:
ΔU₁=R·I₁+L·Îₜ₁
Measurement 2:
ΔU₂=R·I₂+L·Îₜ₂

For ease of resolution, they will be written as follows:

$$R = \frac{{\hat{I}}_{t 1}}{\underline{{I}_{1}}} \cdot L + \frac{\underline{Δ {U}_{1}}}{\underline{{I}_{1}}} ⇔ y = {a}_{1} \cdot x + {b}_{1}$$

$$R = \frac{{\hat{I}}_{t 2}}{\underline{{I}_{2}}} \cdot L + \frac{\underline{Δ {U}_{2}}}{\underline{{I}_{2}}} ⇔ y = {a}_{2} \cdot x + {b}_{2}$$

At present, the system is as follows:

$$\{ \begin{matrix}y = {α}_{1} \cdot x + {b}_{1} \\ y = {α}_{1} \cdot x + {b}_{2}\end{matrix} \qquad [ EQ 17 ]$$

The solutions of the system are as follows:

$$x = \frac{{b}_{2} - {b}_{1}}{{a}_{1} - {a}_{2}} and y = \frac{{a}_{2} \cdot {b}_{1} - {a}_{1} \cdot {b}_{2}}{{a}_{2} - {a}_{1}}$$

which finally yields, after simplifications have been performed:

$$L = \frac{\underline{Δ {U}_{2}} \cdot \underline{{I}_{1}} - \underline{Δ {U}_{1}} \cdot \underline{{I}_{2}}}{{\hat{I}}_{t 2} \cdot \underline{{I}_{1}} - {\hat{I}}_{t 1} \cdot \underline{{I}_{2}}}$$

$$R = \frac{{\hat{I}}_{t 1} \cdot \underline{Δ {U}_{2}} - {\hat{I}}_{t 2} \cdot \underline{Δ {U}_{1}}}{{\hat{I}}_{t 1} \cdot \underline{{I}_{2}} - {\hat{I}}_{t 2} \cdot \underline{{I}_{1}}}$$

1. A method for determining active and reactive loop impedance components of an alternating current supply network providing current at a supply voltage, by measurement of a loop voltage and a loop current, the loop including a network line conductor and at least one of a neutral network conductor, and a protective grounding conductor, the method comprising:
applying a load to the loop;
measuring the loop voltage before a test load is applied;
measuring the loop voltage when the test load is applied measuring the voltage as a function of time during the period in which the test load is applied; and
determining active resistance R and reactive inductance L portions of the loop impedance by conjointly analyzing differential loop voltage measurements and current in the test load as a function of time.

2. (canceled)

3. The method according to claim 1, including obtaining the current by applying the test load through a measuring instrument carrying out the differential measurements of the loop voltage and the measurements of the current as a function of time.

4. The method according to claim 1, including applying the test load on a peak of the voltage.

5. The method according to claim 1, including analyzing the test load close to a peak of the voltage.

6. The method according to claim 1, including applying the test load repeatedly, measuring the voltage and the current as a function of time, repeatedly, and totaling and averaging the measurements over several pulses.

7. The method according to claim 1, including applying the test load repeatedly and measuring the current in at least two pulses per period of the voltage.

8. The method according to claim 6, including, from one period of the voltage to another period, inverting sequence of a pulse before application of the load and of a pulse after application of the load.

9. The method according to claim 8, including obtaining the impedance using integrated measurements of the differential loop voltage and current, respectively.

10. A device for measuring loop impedance comprising:
an input divider bridge for connection to an electrical network for determining loop impedance by measuring voltage and current;
buffer storage;
at least one integrator connected to the divider bridge via the buffer storage;
an on/off control; and
measuring and processing means receiving signals from the at least one integrator, including means for making measurement results available.

11. The method according to claim 1, including determining the active resistance R and reactive portions of the loop impedance using the following formulas for the conjoint analysis:
$$R = \frac{{\hat{I}}_{t 1} \cdot \underline{Δ {U}_{2}} - {\hat{I}}_{t 2} \cdot \underline{Δ {U}_{1}}}{{\hat{I}}_{t 1} \cdot \underline{{I}_{2}} - {\hat{I}}_{t 2} \cdot \underline{{I}_{1}}}$$
$$L = \frac{\underline{Δ {U}_{2}} \cdot \underline{{I}_{1}} - \underline{Δ {U}_{1}} \cdot \underline{{I}_{2}}}{{\hat{I}}_{t 2} \cdot \underline{{I}_{1}} - {\hat{I}}_{t 1} \cdot \underline{{I}_{2}}}$$
where:
Îₜ₁ represents instantaneous value, I_{pic1}, of the current in the test load at the end of a time period T1,
Îₜ₂ represents instantaneous value I_{pic2} of the current in the test load at the end of a time period T2,
ΔU₁ represents maximum voltage difference, (no load−load), during the time period T1,
ΔU₂ represents maximum voltage difference, (no load−no load), during the time period T2,
I₁ represents maximum current in the test load during the time period T1, and
I₂ represents maximum current in the test load during the time period T2.
